(19) United States
(12) Patent Application Publication
(10) Pub. No.: US 2020/0136618 A1
(43) Pub. Date: Apr. 30, 2020

(54) OPTICAL DISPLAY KNOB

(71) Applicant: GM Global Technology Operations LLC, Detroit, MI (US)

(72) Inventors: Zhongya Lou, Windsor (CA); Jayasimha V. Rao, Troy, MI (US); James A. Carpenter, Rochester Hills, MI (US); Michael J. Boesch, Royal Oak, MI (US)

(21) Appl. No.: 16/173,573

(22) Filed: Oct. 29, 2018

(51) Int. Cl. H03K 17/965; G06F 3/0484; B60K 35/00

(52) U.S. Cl. CPC H03K 17/965; G06F 3/04847; B60K 35/00; B60K 2350/1028; B60K 2350/206; B60K 2350/203; B60K 2350/104

(57) ABSTRACT

An optical display knob is mounted on an electronic display, such as a touch-screen display found in a vehicle interior cabin, and includes a knob body with an optical guide and a button located therein. The knob body is rotatable, whereas the optical guide is adhered to the electronic display via a transparent adhesive so that it is stationary, with respect to the electronic display. When the electronic display generates graphics or images, the corresponding light is transmitted through the transparent adhesive and the optical guide to a front display surface. At the front display surface, the graphics appear to be emanating from the front of the optical display knob, and not from the surface of the electronic display itself.

### TECHNICAL FIELD

The present invention relates generally to electronic controls, and more particularly, an optical display knob that is mounted on an electronic display.

### BACKGROUND

Vehicles include various types of knobs and other controls for controlling different vehicle functions, such as the heating/ventilation/air conditioning (HVAC) and the radio.

For example, some vehicles include physical controls, such as knobs or physical buttons, which can be actuated by a vehicle user. Also, some vehicles include a touch-screen display that allows the vehicle user to control various vehicle functions. Touch-screen controls are dynamic in that their associated display (e.g., graphical button and associated text or graphics) can dynamically display graphics including interactive graphics or controls. However, some vehicle users prefer physical controls since the vehicle user can locate and/or operate the physical control by touch, without having to look for the control on the module (e.g., infotainment unit). This can be particularly useful when the vehicle user is driving as they can operate the control without having to take their eyes off of the road.

Thus, it may be desirable to provide a graphically-dynamic physical control that enjoys benefits of both dynamic display graphics and physical controls.

### SUMMARY

According to one aspect, there is provided an optical display knob comprising: an electronic display that includes a knob display portion; a knob body that is rotatably mounted on the electronic display and includes a knob body cavity; an optical guide that is disposed within the knob body cavity and includes a front display surface and a rear surface, the optical guide is made from an optically transmissive material; and a transparent adhesive that is located between the knob display portion and the rear surface and adheres the optical guide to the electronic display. The knob body is aligned with the knob display portion so that when graphics are illuminated at the knob display portion, light is transmitted from the electronic display, through the transparent adhesive, and through the optical guide so that the graphics are displayed on the front display surface.

According to various embodiments, the optical display knob may further include any one of the following features or any technically-feasible combination of some or all of these features:
the electronic display is a touch screen liquid crystal display (LCD);
the knob body is generally cylindrical and includes an outer cylindrical surface, an inner cylindrical surface, a front face, and a back face, the inner cylindrical surface defines the knob body cavity and surrounds the optical guide;
the knob body further includes at least one of an electromagnetic element or an electromagnetic sensor and the electronic display includes at least one of the other of the electromagnetic element or the electromagnetic sensor, the at least one electromagnetic element and sensor are configured to determine the rotational position of the knob body with respect to the electronic display;
the optical guide is a radially-truncated cylinder made from the optically transmissive material and includes the front display surface located at one axial end, the rear surface located at another axial end, an outer cylindrical surface extending between the front display surface and the rear surface, and a bottom surface extending between the front display surface and the rear surface;
the front display surface, the rear surface, and the bottom surface are all planar surfaces, and the outer cylindrical surface is a curved surface that is complementary in shape to an inner cylindrical surface of the knob body;
the optical guide includes a single, unitary component made from the optically transmissive material, the optical guide is coated on at least one surface to promote total internal reflection (TIR) within the optical guide;
the optical guide includes a bundle of separate optical fibers made from the optically transmissive material;
the optical display knob further comprises: a button that is disposed within the knob body cavity and includes a contact, a front display surface and a rear surface, the button is engageable within the knob body cavity and the contact is electrically coupled to the electronic display so as to provide input in response to engagement of the button by a user;
the button is a radially-truncated cylinder and includes the front display surface located at one axial end, the rear surface located at another axial end, an outer cylindrical surface extending between the front display surface and the rear surface, and a top surface extending between the front display surface and the rear surface;
the front display surface and the top surface are planar surfaces, and the outer cylindrical surface is a curved surface that is complementary in shape to an inner cylindrical surface of the knob body;
the optical guide and the button are complementary in shape so that when they are assembled next to one another within the knob body cavity, the bottom surface of the optical guide opposes the top surface of the button and the combined shape of the optical guide and the button approximates that of a full cylinder;
the front display surface of the button includes one or more types of indicia;
the optical guide and the button are assembled within the knob body cavity so that the knob body can rotate while the optical guide and the button remain rotationally stationary, with respect to the electronic display;
the button further includes a button indicator optical guide that transmits light from one or more pixels on the electronic display to the front display surface of the button, the button indicator optical guide being configured to indicate the status of the button to a user;
the transparent adhesive is an optically clear adhesive (OCA) film located between the knob display portion and the rear surface;
the optical display knob further comprises: one or more light-blocking walls that are disposed within the knob body cavity and at least partially surround the optical guide so as to promote light efficiency, light uniformity or both;
the optical display knob further comprises: an anti-reflective (AR) coating provided on the front display surface of the optical guide;
the optical display knob is part of an optical display knob system that is to be installed in an interior cabin of a vehicle, the optical display knob system comprises the display, the optical display knob mounted on the display, and one or more touch screen control(s) or graphic(s) that are formed on the display.

According to another embodiment, there is provided a method of using an optical display knob having an electronic display that includes a knob display portion, a knob body that is rotatably mounted on the electronic display and includes a knob body cavity, an optical guide that is disposed within the knob body cavity and includes a front display surface and a rear surface, and a transparent adhesive that is located between the knob display portion and the rear surface and adheres the optical guide to the electronic display. The method comprises the steps of: illuminating graphics at the knob display portion of the electronic display; transmitting light from the electronic display, through the transparent adhesive, and through the optical guide; and displaying the graphics on the front display surface.

### BRIEF DESCRIPTION OF THE DRAWINGS

One or more embodiments of the invention will hereinafter be described in conjunction with the appended drawings, wherein like designations denote like elements, and wherein:

FIG. 1 is a schematic view of an optical display knob system that includes first and second optical display knobs mounted on a display;

FIG. 2 is an exploded view of the first optical display knob of FIG. 1;

FIG. 3 is a cross-sectional side view of the first optical display knob of FIG. 1 and FIG. 2;

FIG. 4A is a schematic view of a display knob that does not include an optical guide; and

FIG. 4B is a schematic view of a display knob that does include an optical guide.

### DETAILED DESCRIPTION OF THE ILLUSTRATED EMBODIMENT(S)

The optical display knob provided herein enables a rotatable control knob to be mounted on an electronic display, such as a touch-screen display found in a vehicle interior cabin, in such a way that graphics or images originating at the electronic display are transmitted through an optical guide in the knob to a front display surface. This causes the graphics or images to appear to be at the front display surface of the optical display knob, as opposed to at a rear surface within the depth of the knob, which can cause obscuration due to parallax or other phenomena. Thus, by bringing the graphics or images to a front display surface, the optical display knob described herein improves the readability, design flexibility and/or other characteristics of the knob.

According to one example, the optical display knob is mounted on a knob display portion of the electronic display and includes a knob body with an optical guide and a button located therein. The knob body is rotatable, whereas the optical guide is adhered to the electronic display so as to be stationary, with respect to the electronic display. When the electronic display generates graphics or images at the knob display portion, which is the section or area of the display to which the optical guide is coupled, the corresponding light from the display is transmitted or conveyed through the optical guide to the front display surface. At the front display surface, the graphics or images appear to be emanating from the front of the optical display knob, and not from the surface of the electronic display itself. This improves the readability of the optical display knob, regardless of the parallax (or viewing angle of a viewer).

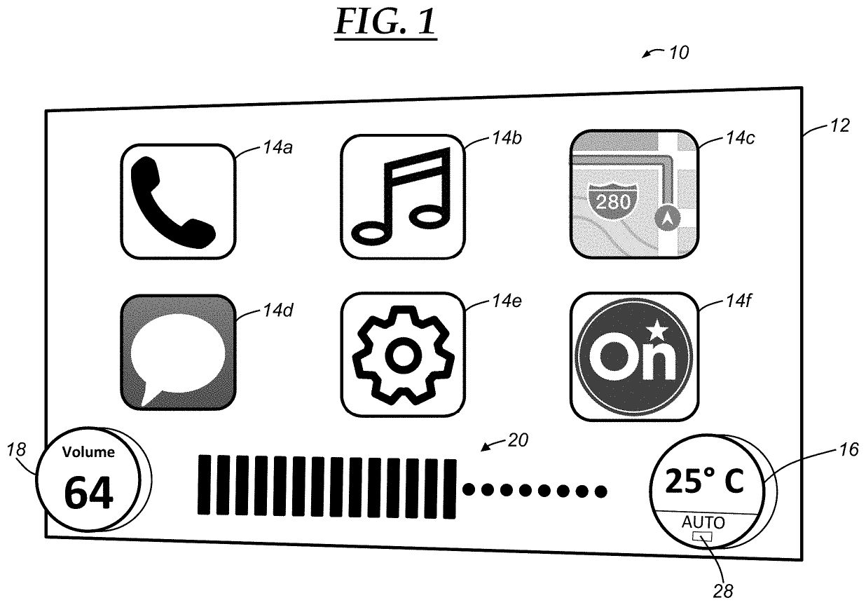

FIG. 1 illustrates one possible architecture for an optical display knob system 10 that can include one or more optical display knobs 16, 18. While the present description is directed to the optical display knob system shown in FIGS. 1 through 3, one of ordinary skill in the art will appreciate that optical display knob system 10 is merely one example, and in many ways, the diagrams of these figures have been simplified for ease of explanation. The optical display knob system and/or the optical display knob are not limited to the particular embodiments described herein and may be used in any number of different applications, including both vehicle and non-vehicle applications, and with any number of different configurations. In one such example, the optical display knob system and/or the optical display knob are used with a consumer electronic device (e.g., a video game console) or a household appliance (e.g., a washer, dryer, microwave, etc.), as opposed to being used with a vehicle display. Other such examples are certainly possible.

In the illustrated embodiment, optical display knob system 10 includes an electronic display 12 that is shown as displaying a plurality of touch-screen controls 14a-f, a first optical display knob 16, a second optical display knob 18, and other (or non-optical display knob) graphics 20. The optical display knob system 10 can be installed in a cabin of a vehicle (not shown) and may be part of a vehicle infotainment module, an instrument panel, a center stack, etc.

The electronic display 12 can be used to display various graphics or other types of information. The display can be a can be a liquid crystal display (LCD), a plasma display, a light-emitting diode (LED) display, an organic LED (OLED) display, or other suitable electronic display as appreciated by those skilled in the art. Also, in many embodiments, the electronic display 12 is a touch-screen display that is capable of detecting a touch of a user such that the display acts as both an input and an output device. For example, the touch-screen display 12 can be a resistive touch-screen, capacitive touch-screen, surface acoustic wave (SAW) touch-screen, an infrared touch-screen, or other suitable touch-screen display known to those skilled in the art. According to a non-limiting example, the electronic display 12 is an LCD touch screen display.

The electronic display 12 can be used as a main display for an infotainment unit in a vehicle, or for other purposes, such as an instrument panel. In the illustrated embodiment, the electronic display 12 is shown as displaying a plurality of touch-screen controls 14a-f as well as other graphics 20. As discussed more below, the electronic display 12 may be used to project graphics to the optical display knobs 16 and 18—in the illustrated embodiment, the graphics of the first optical display knob 16 read “25° C.” and the graphics of the second optical display knob 18 read “Volume” and “64,” both of which may be projected or otherwise provided by the display 12. Also, the electronic display 12 can provide the light that is used to illuminate a separate button indicator on the display knob, such as the button indicator optical guide 28 of the first optical display knob 16. In the illustrated embodiment, optical display knob 16 can be used to provide input to a heating/ventilation/air conditioning (HVAC) system of the vehicle and optical display knob 18 can be used to provide input to an entertainment system (e.g., radio) of the vehicle. However, the optical display knobs 16 and/or 18 can be used with any number of other displays and for a variety of other purposes.

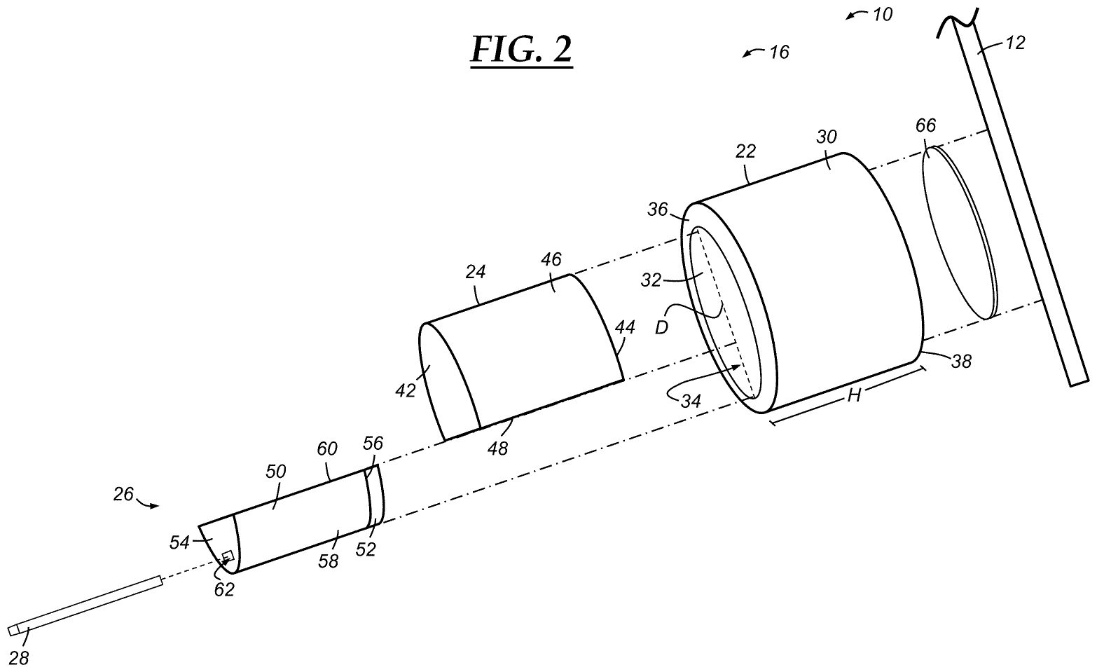

With reference to FIG. 2, there is shown an exploded view of the first optical display knob 16. The optical display knob 16 includes a knob body 22, an optical guide 24, and a button 26 that includes a button indicator optical guide 28. The knob body 22 is generally cylindrical and has a circular cross-section with an inner diameter D and an axial height H. The knob body 22 includes an outer cylindrical surface 30, an inner cylindrical surface 32 that defines a knob body cavity 34, a front face 36, and a back face 38. The phrase “generally cylindrical,” as used herein, means that the knob body and/or one of the corresponding surfaces can be cylindrical in shape or be cylindrical with a slight taper. The knob body 22 can be made of plastics (e.g., thermoplastics or other polymers), metal, glass, or other suitable materials. The outer cylindrical surface 30 can be smooth or can be textured so as to improve the grip of a user, for example. The inner cylindrical surface 32 is preferably smooth; however, in other embodiments, the inner cylindrical surface 32 can be textured. In one embodiment, the knob body 22 is a unitary structure.

The knob body 22 may include any type of suitable circuitry and/or elements for detecting the rotational position of the knob. For instance, it is possible that the back face 38 of the knob body have some type of electromagnetic elements mounted or otherwise embedded therein so that corresponding electromagnetic sensors on the adjacent surface of the electronic display 12 can accurately detect the rotational position of the knob as it is turned by the user. Other types of sensor arrangements, such as ones where electromagnetic elements mounted on the inner cylindrical surface 32 of the knob body interact with electromagnetic sensors somewhere in the knob body cavity 34, may be used instead. The knob body 22 and its corresponding circuitry are not limited to any particular arrangement, as they may include any appropriate type of electromagnetic, electromechanical, capacitive and/or other type of rotation sensing elements. Also, the knob body 22 and/or other parts of the optical display knob 16 may include a mechanism that provides haptic or tactile feedback to a user—for example, the knob can “click” or otherwise provide a sensation as the knob body 22 is rotated by a user. This haptic or tactile feedback can intuitively convey the rotational extent to which the knob body 22 has been turned, without the user having to look at the knob or other device, such as the display 12.

The optical guide 24 delivers light from the electronic display 12 to a front display surface 42. In many embodiments, the optical guide 24 is or functions as a waveguide or light pipe that receives light waves from the electronic display 12 and transmits them to the front display surface 42 so that corresponding graphics can be easily seen by the user. In some embodiments, the optical guide 24 can be (or function as) a lens of some sort that magnifies, de-magnifies, refracts and/or otherwise influences the appearance of the graphics as the light is transmitted to the front display surface 42; in other embodiments, the optical guide 24 simply conveys the light from the display 12 to the front display surface 42 without distortion. In addition to the front surface (or front display surface) 42, the optical guide 24 of the first optical display knob 16 includes a rear surface 44, an outer cylindrical surface 46, and a bottom surface 48. The front surface 42, the rear surface 44, and the bottom surface 48 may be planar surfaces, whereas the outer cylindrical surface 46 may be curved according to the shape of the inner cylindrical surface 36 so as to fit within the knob body cavity 34. The bottom surface 48 can be rectangular. According to this particular embodiment, the optical guide 24 is shaped as a radially-truncated cylinder, which is a cylinder that is truncated or sliced along a plane that is parallel to the central axis of the optical guide. For example, in the illustrated embodiment, the optical guide 24 is sliced along a plane that extends between the front surface 42 and the rear surface 44 and defines the bottom surface 48. Other geometric shapes and configurations are certainly possible, however, as this is only one possibility.

The optical guide 24 may be made from any suitable type of optically transmissive material. A non-limiting example includes an optical carbon polymer, such as a glass optical material made from silica or fluoride glass, but other materials could be used instead. It is possible for the optical guide 24 to be a single, unitary component (e.g., a one-piece component made of a homogenous material) or to include a number of separate light conducting elements (e.g., a bundle of optical fibers or pipes). Various manufacturing processes can be used to manufacture the optical guide, as is appreciated by those skilled in the art. The optical guide 24 can be coated to better achieve total internal reflection (TIR) within the guide, such as with urethane acrylates, polyimides, etc., but this is not required. According to one example, the front display surface 42 of the optical guide 24 is designed to be “dead fronted,” so that the display surface appears black when not in use, but displays various graphics or indicia when being illuminated by the electronic display 12 and optical guide 24. Other embodiments are certainly possible.

The button 26 includes a button body 50, a contact 52, and a button indicator optical guide 28. In one embodiment, the button body 50 is a single, unitary structure and can be made of any suitable optically transmissive material, including those described above. The button body 50 includes a front display surface 54, a rear surface 56, an outer cylindrical surface 58, a top surface 60, and a button indicator cavity 62. The button body 50 may be shaped as a radially-truncated cylinder, similar and complementary in shape to that of the optical guide 24, so that when the optical guide 24 and button 26 are assembled next to one another within the knob body cavity 34, their combined shapes approximate that of a full cylinder. In one non-limiting example, the button 26 is shaped as a cylinder that is truncated or sliced along a plane that is parallel to the central axis of the button. For example, in the illustrated embodiment, the button 26 is sliced along a plane that extends between the front surface 54 and the rear surface 56 and defines the top surface 60. In this embodiment, the top surface 60 of the button body 50 includes an area equal (or at least substantially equal) to the bottom surface 48 of the optical guide 24 such that the two planar surfaces oppose one another within the knob body cavity 34. In one embodiment, the front display surface 54 of the button body 50 includes static text, images (e.g., 2D or 3D images), holograms, or graphics that can be laser-etched or otherwise formed to be visible to the user. The preceding possibilities apply to front display surface 42 and/or 54. In the illustrated embodiment of FIG. 1, text is provided on the front display face 54 and reads “AUTO,” although other static and/or dynamic text may be provided instead.

The top surface 60 of the button body 50 can be shaped the same as the bottom surface 48 of the optical guide 24. As will be discussed in more detail below, a light blocking wall can be positioned between the bottom surface 48 of the optical guide 24 and the top surface 60 of the button body 50 so as to prevent light from escaping the main optical guide 24, but this is not necessary. When the button body 50 and the main optical guide 24 are assembled within the knob body cavity 34, the bottom surface 48 and top surface 60 complement and potentially contact one another (e.g., they can both be planar surfaces that slide past one another when the button is depressed by a user). The radius (or curvature) of the outer cylindrical surface 46 of the optical guide 24 and the outer cylindrical surface 58 of the button body 50 is slightly smaller than that that of the inner cylindrical surface 32 of the knob body 22. This allows the optical guide 24 and the button 26 to fit snugly and within the knob body cavity 34 while still allowing for rotation of the knob body 22 around its central axis. Put differently, the optical guide 24 and the button 26 can be assembled within the knob body cavity 34 so that knob body 22 can rotate while the optical guide and the button remain rotationally stationary, with respect to the electronic display 12.

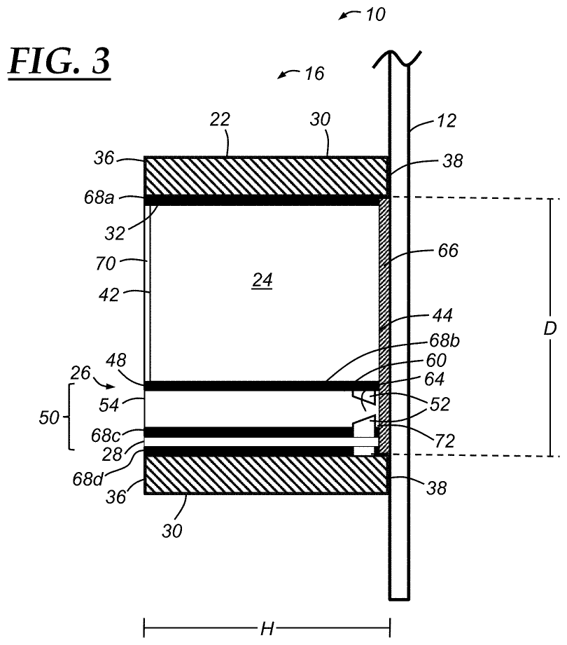

The contact 52 is an electrical contact and is embedder in and/or otherwise is provided near the rear surface 56 of the button body 50. The contact 52 can include a similar or the same cross-sectional area of the button body when sliced orthogonal to its length. The contact 52 can be attached to an attachment portion 64 (FIG. 3) of the button body 50, which is discussed in more detail below. As its name suggests, the contact 52 generally acts as an electrical contact so that when a user depresses button 26, an electrical connection can be made between contact 52 and a corresponding contact located on the electronic display 12. This enables a user to independently engage or activate the button 26, without engaging other aspects of the display knob. In some embodiments, instead of using a contact 52 on the rear surface 56, the button body 50 (or other portion on the rear surface 56) can be used to depress part of the electronic display 12, which in turn makes an electrical connection that provides input into the display 12 (in this embodiment, the electrical contact is on the display 12). For example, such an embodiment can be used when the electronic display is a resistive type touch-screen. The contact 52 does not have to be an electromechanical physical contact, as it could be any appropriate type of electromagnetic, electromechanical, capacitive and/or other type of contact or sensing element that is coupled to the electronic display 12.

The button indicator optical guide 28 delivers or conveys light from the electronic display 12 to the front display surface 42 and/or 54. In many embodiments, the button indicator optical guide 28 is or functions as a waveguide or light pipe that transmits light from pixels on the electronic display 12 to the front display surface 54 (e.g., to illuminate a “jewel” on the front display surface). The button indicator optical guide 28 can be made of any of the materials discussed above with respect to the optical guide 24, it can be coated to promote TIR, or it can be made with other materials. In one embodiment, the button indicator optical guide 28 is manufactured separately from the button 26 and is configured to fit snugly within the button indicator cavity 62; in different embodiments, the button indicator optical guide 28 is co-molded with the button 26, but as a different material, so that the two parts are manufactured together, or the button indicator optical guide 28 is 3D optical printed. The button indicator optical guide 28 may be shaped as an elongated cuboid that includes three pairs of parallel surfaces, wherein the surfaces of a first pair are orthogonal to the surfaces of the second and third pair, and the surfaces of the second pair are orthogonal to the surfaces of the third pair, but other arrangements are possible as well.

With reference to FIG. 3, there is shown a cross-sectional view of the optical display knob 16. As illustrated, the knob body 22 surrounds the optical guide 24 and the button 26, and the button body 50 surrounds the button indicator optical guide 28. The contact 52 is attached to the attachment portion 64 of the button body 50 so as to oppose a corresponding contact or other element on the electronic display 12. In the illustrated embodiment, the attachment portion 64 is a portion of the button body 50 that protrudes out from the rear surface 56 of the button body 50. The contact 52 may include a cavity that surrounds the attachment portion 64, which in turn may be frusto-conically shaped and, as depicted, and can taper inwardly so that the diameter (or cross-sectional area) is reduced as it extends away from the button body 50. The contact 52 can be attached to the attachment portion 64 via an adhesive or via other attachment means, such as through use of an elastic button electrical member that is elastically deformed and placed over the attachment portion 64—in such a case, the elastic resiliency of the contact 52 holds on to the attachment portion 64. Other electrical contact arrangements are certainly possible.

The optical guide 24 and the button 26 are secured to the electronic display 12 via a transparent adhesive 66. The transparent adhesive layer 66 preferably includes an optically clear adhesive (OCA), and can be provided in the form of a thin OCA tape or film. In one embodiment, an OCA tape or film (collectively referred to as an OCA film) can be provided in situ and used as the adhesive layer 66. Transparent adhesive 66 allows light from the electronic display 12 to be transmitted through the adhesive layer 66 to the optical guide 24 and/or the button indicator optical guide 28, preferably with little to no distortion. In another embodiment, the adhesive layer 66 can be a liquid optically clear adhesive (LOCA). Other embodiments are possible as well.

The optical display knob 16 can also include one or more light-blocking walls 68 that surround the optical guide 24 and the button indicator optical guide 28 so as to prevent or at least minimize light from the electronic display 12 from escaping the optical guides 24 and 28. As depicted in FIG. 3, the optical display knob 16 may include four light-blocking walls 68a-d. The first light-blocking wall 68a is provided between the inner cylindrical surface 32 of the knob body 22 and the outer cylindrical surface 46 of the optical guide 24. The second light-blocking wall 68b is provided between the bottom surface 48 of the optical guide 24 and the top surface 60 of the button body 50. The third light-blocking wall 68c is provided between a top inner cavity wall of the button indicator cavity 62 and a top outer surface of the button indicator optical guide 28. The fourth light-blocking wall 68d is provided between a bottom inner cavity wall of the button indicator cavity 62 and a bottom outer surface of the button indicator optical guide 28.

In one embodiment, the light-blocking walls 68a-d can be separate opaque elements or pieces that are provided within the knob body cavity 34 so as to promote light efficiency and/or uniformity. In another embodiment, the light-blocking walls 68a-d can be part of the optical guide 24, the button body 50, and/or the button indicator optical guide 28—for example, the light-blocking walls 68a-d can be a coating that is applied to the optical guide 24 and/or the button indicator optical guide 28. This light-blocking coating can prevent, or at least minimize, light from escaping the optical guides 24 and 28 so that the brightness of the display is maintained at the front display surface 42 of the optical guide 24 and the front display surface of the button indicator optical guide 28.

The optical guide 24 can be provided with any number of different types of coating 70 that is provided on the front display surface 42. For example, the coating 70 may be an anti-reflective (AR) coating that prevents glare or other undesirable reflections, it may be an anti-fingerprint coating, an anti-microbial coating, or any other suitable surface coating. The coating 70 is a transparent thin film that can be provided to the surface of the optical guide 24. In some embodiments, the front surface of the button indicator optical guide 28 can be provided with a coating as well. However, in some embodiments, the coating on the front surface of the button indicator optical guide 28 can be omitted.

The button 26 includes a button gap 72 that permits the button body 50 to be depressed. When the button body 50 is depressed, the contact 52 electrically contacts or otherwise provides input to the electronic display 12. For example, when the contact 52 moves closer to a touch-screen display 12, the electrical properties of the electrically-conductive contact 52 can cause the electronic display 12 to sense input and, thus, it can be determined that the button 26 is (or has been) depressed. In another example, as mentioned above, instead of using an electromechanical physical contact 52, the button 26 can be depressed and can provide pressure onto the knob display potion of the electronic screen 12 at an area adjacent to the button gap 72—this pressure can be sensed by the display 12 and used to determine that the button 26 has been depressed. Any number of other button arrangements, including ones that are capacitively coupled to the electronic screen 12, may be used instead.

The optical display knob 18, which represents another embodiment of the optical display knob, may include an optical guide and a knob body, but does not include a button 26. The knob body of the optical display knob 18 can be substantially the same as knob body 22. The optical guide of the optical display knob 18 can be made of the same material as the optical guide 24, and can be used in the same manner as the optical guide of the optical display knob 16—that is, to transmit or guide light from the knob display portion of the electronic display 12 to the front display surface of the optical guide. However, the optical guide of the optical display knob 18 is preferably a whole cylinder, as opposed to a radially-truncated cylinder, and is configured to fit within the knob body cavity. The optical display knob 18 includes a single light blocking wall that circumscribes or surrounds the outer circumferential surface of the optical guide. This light blocking wall can be similar in construction or makeup to those light blocking walls 68a-d of the optical display knob 16.

In other embodiments, the optical display knob 16 and/or 18 can include one or more additional inputs that can be mechanically and/or electronically actuated so that additional input is provided into the electronic display 12. For example, the optical display knob 16 and/or 18 can include one or more additional push-buttons.

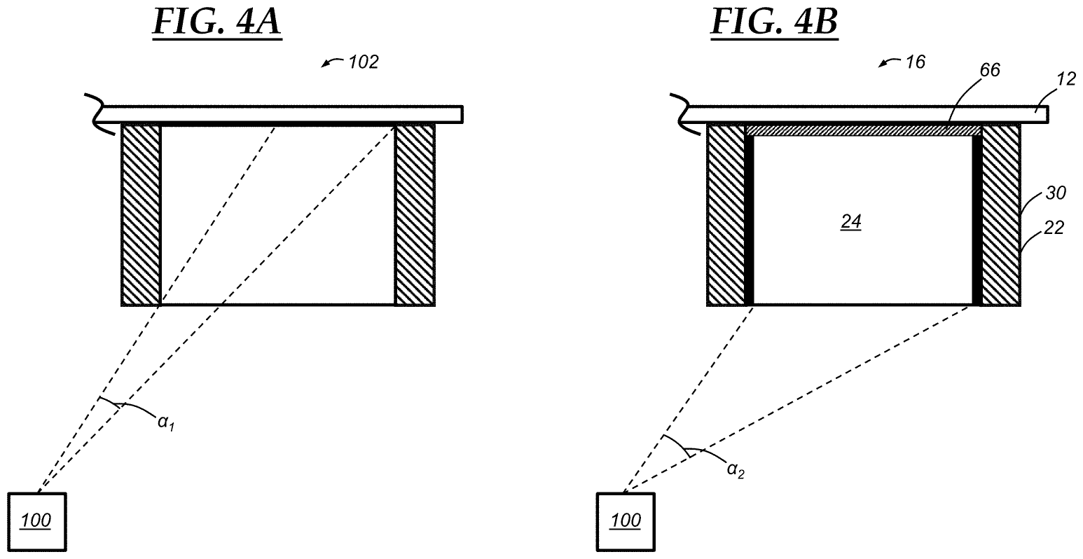

FIG. 4A schematically depicts an overhead view of a standard display knob 102 being viewed by a user 100, while FIG. 4B schematically depicts an overhead view of the optical display knob 16 being viewed by the user 100. The user 100 is located at the same location relative to the display knob 102 and the optical display knob 16, and thus, is positioned at the same viewing angle. As illustrated, the user 100 views graphics from within the display knob 102 at a relatively small, first display angle α₁; whereas the viewer 100 views graphics from within the display knob 16 at a larger second display angle α₂. The second display angle α₂ is much larger than the first display angle α₁ and, as illustrated in FIGS. 4A and 4B, the user 100 can see more of the display surface when viewing the graphics as presented on the optical display knob 16 compared to those presented on the standard display knob 102. The user 100 may be able to see the entire display of the optical display knob 16, but can only see a portion (e.g., 40%) of the display when viewing the standard display knob 102. In one embodiment where the optical display knob system is installed in an infotainment unit of a vehicle, the optical display knob 16 can prove useful for a vehicle driver (or other user) since the vehicle user will likely be viewing the display of the display knob at a non-zero viewing angle (i.e., not straight-on), such as that which is depicted in FIGS. 4A and 4B. It should be appreciated that the deeper the control knob (i.e., the greater the axial length of the control knob), the more pronounced the viewing angle or parallax problem is. Thus, not only is the present optical display knob more readable, but it also provides greater design flexibility, as deeper knobs are possible.

In operation, . . . knob rotates, while main optical guide stays stationary . . .

It is to be understood that the foregoing description is not a definition of the invention, but is a description of one or more preferred exemplary embodiments of the invention. The invention is not limited to the particular embodiment(s) disclosed herein, but rather is defined solely by the claims below. Furthermore, the statements contained in the foregoing description relate to particular embodiments and are not to be construed as limitations on the scope of the invention or on the definition of terms used in the claims, except where a term or phrase is expressly defined above. Various other embodiments and various changes and modifications to the disclosed embodiment(s) will become apparent to those skilled in the art. For example, the specific combination and order of steps is just one possibility, as the present method may include a combination of steps that has fewer, greater or different steps than that shown here. All such other embodiments, changes, and modifications are intended to come within the scope of the appended claims.

As used in this specification and claims, the terms “for example,” “e.g.,” “for instance,” “such as,” and “like,” and the verbs “comprising,” “having,” “including,” and their other verb forms, when used in conjunction with a listing of one or more components or other items, are each to be construed as open-ended, meaning that that the listing is not to be considered as excluding other, additional components or items. Other terms are to be construed using their broadest reasonable meaning unless they are used in a context that requires a different interpretation. In addition, the term “and/or” is to be construed as an inclusive or. As an example, the phrase “A, B, and/or C” includes: “A”; “B”; “C”; “A and B”; “A and C”; “B and C”; and “A, B, and C.”

1. An optical display knob, comprising:
an electronic display that includes a knob display portion;
a knob body that is rotatably mounted on the electronic display and includes a knob body cavity;
an optical guide that is disposed within the knob body cavity and includes a front display surface and a rear surface, the optical guide is made from an optically transmissive material; and
a transparent adhesive that is located between the knob display portion and the rear surface and adheres the optical guide to the electronic display;
wherein the knob body is aligned with the knob display portion so that when graphics are illuminated at the knob display portion, light is transmitted from the electronic display, through the transparent adhesive, and through the optical guide so that the graphics are displayed on the front display surface.

2. The optical display knob of claim 1, wherein the electronic display is a touch screen liquid crystal display (LCD).

3. The optical display knob of claim 1, wherein the knob body is generally cylindrical and includes an outer cylindrical surface, an inner cylindrical surface, a front face, and a back face, the inner cylindrical surface defines the knob body cavity and surrounds the optical guide.

4. The optical display knob of claim 3, wherein the knob body further includes at least one of an electromagnetic element or an electromagnetic sensor and the electronic display includes at least one of the other of the electromagnetic element or the electromagnetic sensor, the at least one electromagnetic element and sensor are configured to determine the rotational position of the knob body with respect to the electronic display.

5. The optical display knob of claim 1, wherein the optical guide is a radially-truncated cylinder made from the optically transmissive material and includes the front display surface located at one axial end, the rear surface located at another axial end, an outer cylindrical surface extending between the front display surface and the rear surface, and a bottom surface extending between the front display surface and the rear surface.

6. The optical display knob of claim 5, wherein the front display surface, the rear surface, and the bottom surface are all planar surfaces, and the outer cylindrical surface is a curved surface that is complementary in shape to an inner cylindrical surface of the knob body.

7. The optical display knob of claim 1, wherein the optical guide includes a single, unitary component made from the optically transmissive material, the optical guide is coated on at least one surface to promote total internal reflection (TIR) within the optical guide.

8. The optical display knob of claim 1, wherein the optical guide includes a bundle of separate optical fibers made from the optically transmissive material.

9. The optical display knob of claim 1, further comprising:
a button that is disposed within the knob body cavity and includes a contact, a front display surface and a rear surface, the button being engageable within the knob body cavity and the contact being electrically coupled to the electronic display so as to provide input in response to engagement of the button by a user.

10. The optical display knob of claim 9, wherein the button is a radially-truncated cylinder and includes the front display surface located at one axial end, the rear surface located at another axial end, an outer cylindrical surface extending between the front display surface and the rear surface, and a top surface extending between the front display surface and the rear surface.

11. The optical display knob of claim 10, wherein the front display surface and the top surface are planar surfaces, and the outer cylindrical surface is a curved surface that is complementary in shape to an inner cylindrical surface of the knob body.

12. The optical display knob of claim 9, wherein the optical guide and the button are complementary in shape so that when they are assembled next to one another within the knob body cavity, the bottom surface of the optical guide opposes the top surface of the button and the combined shape of the optical guide and the button approximates that of a full cylinder.

13. The optical display knob of claim 9, wherein the front display surface of the button includes one or more types of indicia.

14. The optical display knob of claim 9, wherein the optical guide and the button are assembled within the knob body cavity so that the knob body can rotate while the optical guide and the button remain rotationally stationary, with respect to the electronic display.

15. The optical display knob of claim 9, wherein the button further includes a button indicator optical guide that transmits light from one or more pixels on the electronic display to the front display surface of the button, the button indicator optical guide being configured to indicate the status of the button to a user.

16. The optical display knob of claim 1, wherein the transparent adhesive is an optically clear adhesive (OCA) film located between the knob display portion and the rear surface.

17. The optical display knob of claim 1, further comprising:
one or more light-blocking walls that are disposed within the knob body cavity and at least partially surround the optical guide so as to promote light efficiency, light uniformity or both.

18. The optical display knob of claim 1, further comprising:
an anti-reflective (AR) coating provided on the front display surface of the optical guide.

19. The optical display knob of claim 1, wherein the optical display knob is part of an optical display knob system that is to be installed in an interior cabin of a vehicle, the optical display knob system comprises the display, the optical display knob mounted on the display, and one or more touch screen control(s) or graphic(s) that are formed on the display.

20. A method of using an optical display knob having an electronic display that includes a knob display portion, a knob body that is rotatably mounted on the electronic display and includes a knob body cavity, an optical guide that is disposed within the knob body cavity and includes a front display surface and a rear surface, and a transparent adhesive that is located between the knob display portion and the rear surface and adheres the optical guide to the electronic display, the method comprising the steps of:
illuminating graphics at the knob display portion of the electronic display;
transmitting light from the electronic display, through the transparent adhesive, and through the optical guide; and
displaying the graphics on the front display surface.
